(19) United States
(12) Patent Application Publication
(10) Pub. No.: US 2008/0213699 A1
(43) Pub. Date: Sep. 4, 2008

(54) PHOTORESIST COMPOSITION AND METHOD OF FORMING A PHOTORESIST PATTERN USING THE PHOTORESIST COMPOSITION

(75) Inventor: Sang-Sik MOON, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/101,745

(22) Filed: Apr. 11, 2008

Related U.S. Application Data
(63) Continuation-in-part of application No. 11/303,592, filed on Dec. 15, 2005, now abandoned.

(30) Foreign Application Priority Data
Dec. 17, 2004 (KR) 2004-107663

(51) Int. Cl. G03F 7/004; G03F 7/00

(52) U.S. Cl. 430/286.1; 430/322

(57) ABSTRACT

In a photoresist composition and a method of forming a photoresist pattern using the photoresist composition, the photoresist composition includes a photosensitive polymer having a first repeating unit of p-hydroxystyrene and a second repeating unit of an acrylate at a molar ratio of from about 40:60 to about 60:40, a photosensitive material and an organic solvent. The photoresist composition having good reproducibility and stability may form a photoresist film having a substantially uniform thickness, and may form a fine pattern with accuracy.

### CROSS REFERENCE TO RELATED APPLICATIONS

This application of a continuation-in-part of U.S. patent application Ser. No. 11/303,592 filed on Dec. 15, 2005, which claims priority under 35 U.S.C. § 119 to Korean Patent Application No. 2004-107663 filed on Dec. 17, 2004 in the Korean Intellectual Property Office. The entire contents of both of these applications are herein incorporated by reference.

### BACKGROUND

1. Field

This relates to a photoresist composition. More particularly, this relates to a photoresist composition for forming a pattern in a semiconductor manufacturing process and a method of forming a photoresist pattern using the photoresist composition.

2. Description of the Related Art

Semiconductor devices having a high degree of integration and a rapid response speed are increasingly desirable as information processing apparatuses have been developed. Hence, the technology of manufacturing these semiconductor devices has been developed to improve the degree of integration, reliability and response speed of the semiconductor devices. Particularly, the requirements for a microprocessing technology such as a photolithography process have become stringent.

In a semiconductor manufacturing process, a photoresist composition is used in the photolithography process. Solubility of the photoresist composition varies with respect to the developing solution in accordance with its properties relating to exposure to light. Thus, an image corresponding to a light-exposed pattern can be obtained. A photoresist is generally classified into a positive photoresist and a negative photoresist. In the positive photoresist, the light-exposed portion has an enhanced solubility in the developing solution. The light-exposed portion of the positive photoresist is removed in a developing process so that a desired pattern is obtained. On the other hand, the light-exposed portion of the negative photoresist has a reduced solubility in the developing solution. Thus, an unexposed portion of the negative photoresist is removed in the developing process to form a desired pattern. The photoresist composition generally includes a polymeric component. The polymer in the photoresist composition is required to have certain characteristics such as a high solubility in the solvent used in the coating process, a low light-absorbance at the wavelength of the source, thermal stability, good adhesion properties, etc.

As semiconductor manufacturing processes become more complicated and the degree of integration of a semiconductor device increases, a photoresist composition used for forming an extremely fine pattern is required. The extremely fine pattern is not formed using a conventional photoresist composition.

A copolymer represented by a following chemical structure has been used in the photoresist composition.

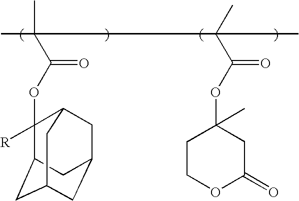

The copolymer includes an adamantyl group and a lactone group. The adamantyl group increases the dry-etching resistance of the photoresist, and the lactone group improves the adhesion characteristics of the photoresist. The copolymer serves to improve resolution and depth of focus of photoresist. However, the dry-etching resistance of the photoresist is not sufficiently enhanced, and a line-edge roughness (LER) of the photoresist pattern that is formed using the copolymer is observed.

In addition, an alternate copolymer of cycloolefin-maleic anhydride (COMA) is represented by the following structure which is disclosed in U.S. Pat. No. 5,843,624.

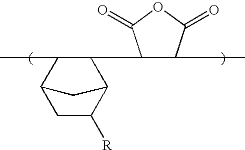

Raw materials of the alternate copolymer are relatively cheap, and thus the alternate copolymer is economically desirable. However, the alternate copolymer is prepared in very low yield. The alternate copolymer also has an excessively low transmittance in a short wavelength region.

Therefore, a need remains for a photoresist composition capable of forming a photoresist film having a uniform thickness, reducing line-edge roughness, and providing good reproducibility and high resolution.

### SUMMARY

Certain embodiments herein provide a photoresist composition including a photosensitive polymer. Other embodiments also provide a method of forming a photoresist pattern using the photoresist composition capable of forming a photoresist film having a uniform thickness, reducing line-edge roughness, and providing good reproducibility and high resolution.

According to one embodiment, a photoresist composition can be provided comprising a photosensitive polymer consisting essentially of a first repeating unit (a) represented by chemical formula (1) and a second repeating unit (b) represented by chemical formula (2), (a) and (b) being at a molar ratio of from about 40:60 to about 60:40,

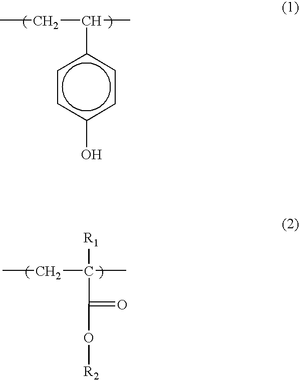

wherein R₁ represents hydrogen or an alkyl group having 1 to 10 carbon atoms and R₂ represents an acid-labile hydrocarbon group having 3 to 12 carbon atoms. In one embodiment, R₁ may represent a methyl group, an ethyl group, a propyl group or a butyl group. In another embodiment, R₂ may represent a tert-butyl group, a tetrahydropyranyl group or a 1-ethoxyethyl group. The photoresist composition can also include a photosensitive material and an organic solvent. In some embodiments, (a) and (b) may be at a molar ratio of from about 45:55 to about 55:45. In other embodiments, (a) and (b) may be at a molar ratio of about 1:1.

In a further embodiment, the photosensitive polymer may have a weight-average molecular weight in a range of from about 5,000 up to about 50,000. In still another embodiment, the photosensitive polymer may have a weight-average molecular weight in a range of from about 10,000 up to about 20,000.

In one embodiment the photoresist composition may comprise from about 1 to up to about 15 parts by weight of the photosensitive material, based on about 100 parts by weight of the photosensitive polymer. In another embodiment, the photosensitive material may comprise at least one of a triarylsulfonium salt, a diaryliodonium salt, a sulfonate and an N-hydroxysuccinimide triflate. In still another embodiment, the organic solvent may comprise at least one of ethylene glycol monomethyl ether, ethylene glycol monoethyl ether, propylene glycol methyl ether, methylcellosolve acetate, ethylcellosolve acetate, diethylene glycol monomethyl ether, diethylene glycol monoethyl ether, propylene glycol methyl ether acetate, propylene glycol propyl ether acetate, diethylene glycol dimethyl ether, ethyl lactate, toluene, xylene, methyl ethyl ketone, cyclohexanone, 2-heptanone, 3-heptanone and 4-heptanone. In another embodiment, the photoresist composition may further comprise an organic base. In a further embodiment, the photoresist composition may comprise from about 0.01 up to about 20 parts by weight of the organic base, based on about 100 parts by weight of the photosensitive polymer. In still a further embodiment, the organic base may comprise at least one of triethylamine, triisobutylamine, triisooctylamine, triisodecylamine, diethanolamine and triethanolamine.

A method of forming a photoresist pattern can also comprise forming a photoresist film on an object by coating the object with a photoresist composition including a photosensitive material, an organic solvent and a photosensitive polymer consisting essentially of a first repeating unit (a) represented by chemical formula (1) and a second repeating unit (b) represented by chemical formula (2), (a) and (b) being at a molar ratio of from about 40:60 to about 60:40, a photosensitive material and an organic solvent. Then, the photoresist film is exposed to a light through a mask, and a portion of the photoresist film is removed to form a photoresist pattern. In one embodiment, the photoresist film may be exposed to the light comprising at least one of a G-line ray, an I-line ray, a krypton fluoride laser, an argon fluoride laser, an electron beam or an X-ray. In another embodiment, prior to exposing the photoresist film to the light, the method may further comprise baking of the photoresist film at a temperature of from about 90° C. up to about 120° C. In still another embodiment, the method may further comprise baking of the photoresist film at a temperature of from about 90° C. up to about 150° C. after exposing the photoresist film to the light.

Accordingly, a photoresist composition may prevent a development difference of a photoresist film due to a different wetting time of each portion of the photoresist film with a developing solution. Thus, a photoresist pattern having a uniform thickness may be obtained. Furthermore, when a photoresist pattern is formed using the subject photoresist composition, the photoresist pattern may reduce line edge roughness and an extremely fine pattern may be formed with accuracy. Therefore, a defect generation of a semiconductor device may be prevented and a productivity of a semiconductor manufacturing process may be enhanced.

### BRIEF DESCRIPTION OF THE DRAWINGS

The above and other features and advantages will become more apparent by describing in detailed exemplary embodiments thereof with reference to the accompanying drawings, in which:

FIGS. 1 to 3 are cross-sectional views illustrating a method of forming a photoresist pattern in accordance with an exemplary embodiment;

FIGS. 4 and 5 are views illustrating the thickness distributions of photoresist films after forming the photoresist films using the photoresist compositions prepared in Comparative Example 1 and Example 1;

FIGS. 6 and 7 are SEM photographs illustrating silicon nitride layer patterns etched using photoresist patterns as etching masks, the photoresist patterns being formed using photoresist compositions prepared in Comparative Example 1 and Example 1;

FIGS. 8 and 9 are SEM pictures showing the photoresist patterns formed using the photoresist compositions of Example 1 and Comparative Example 2; and

FIGS. 10 to 13 are SEM pictures showing the photoresist patterns formed using the photoresist compositions of Examples 1 and 2 and Comparative Examples 3 and 4.

### DETAILED DESCRIPTION

The following provides a more detailed description, with reference to the accompanying drawings, of certain embodiments as are hereinafter shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Photosensitive Polymer

A photosensitive polymer, in one embodiment, has a weight-average molecular weight of from about 1,000 up to about 100,000, and a repeating unit including a first repeating unit (a) of p-hydroxystyrene represented by chemical formula (1) and a second repeating unit (b) of an acrylate represented by chemical formula (2), (a) and (b) being at a molar ratio of from about 40:60 to about 60:40,

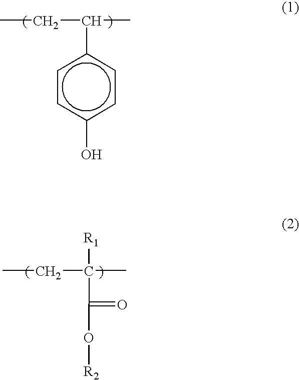

wherein R₁ represents hydrogen or an alkyl group having 1 to 10 carbon atoms and R₂ represents an acid-labile hydrocarbon group having 3 to 12 carbon atoms.

In some example embodiments, the photosensitive polymer may be a random copolymer of p-hydroxystyrene and an acrylate. In other example embodiments, the photosensitive polymer may be an alternate copolymer of p-hydroxystyrene and an acrylate.

In some example embodiments, the molar ratio between p-hydroxystyrene and an acrylate may be approximately about 50:50, i.e., about 1:1. In other embodiments, the molar ratio can have about a 10-20% variation in the value. For example, if the molar ratio were in a range from about 45:55 to about 55:45, it would be considered to be a 10% variation. In a 20% variation, the molar ratio may be in a range from about 40:60 to about 60:40. When the molar ratio between p-hydroxystyrene and an acrylate is less than about 40:60 or greater than about 60:40, a line width roughness of a photoresist pattern may greatly increase, a bridge between patterns may occur, and a profile of a photoresist pattern may become poor.

In an embodiment, R₁ in the chemical formula (2) can represent a methyl group, an ethyl group, a propyl group or a butyl group, and in another embodiment, a methyl group.

In a further embodiment, R₂ in the above chemical formula (2) can represent a tert-butyl group, a tetrahydropyranyl group or a 1-ethoxyethyl group.

When a photoresist film is formed using a photoresist composition including the photosensitive polymer having the weight-average molecular weight of less than about 5,000, a photoresist film having a sufficient thickness may not be obtained, which is unacceptable. In addition, when the photosensitive polymer has the weight-average molecular weight of greater than about 50,000, the photoresist film may not adequately dissolve in a developing solution and thus photoresist scum may remain. Therefore, in one embodiment, the photosensitive polymer of the present invention may have a weight-average molecular weight in a range of from about 5,000 up to about 50,000, and in another embodiment, the weight-average molecular weight in a range of from about 10,000 up to about 20,000.

In an example embodiment, the photosensitive polymer may be applied to a photoresist employing an ArF laser. The ArF laser can be used for a high resolution imaging. The photosensitive polymer having the above molar ratio range can produce an enhanced profile formed in a fine pattern and having a substantially reduced line edge roughness, as compared with a copolymer having other molar ratios. Thus, the photosensitive polymer may be advantageously used as a photoresist for a high resolution imaging such as employing an ArF laser.

Photoresist Composition

A photoresist composition in one embodiment includes a photosensitive material, an organic solvent and a photosensitive polymer having a first repeating unit (a) represented by chemical formula (1) and a second repeating unit (b) represented by chemical formula (2), (a) and (b) being at a molar ratio of from about 40:60 to about 60:40,

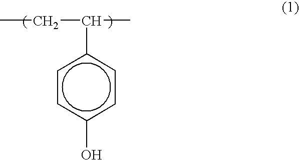

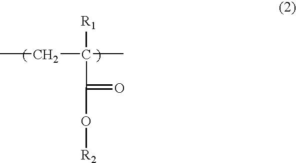

wherein R₁ represents hydrogen or an alkyl group having 1 to 10 carbon atoms and R₂ represents an acid-labile hydrocarbon group having 3 to 12 carbon atoms.

In the photoresist composition according to an example embodiment, R₁ in the chemical formula (2) may represent a methyl group, an ethyl group, a propyl group or a butyl group, and in a further embodiment, a methyl group. R₂ in the chemical formula (2) may represent a tert-butyl group, a tetrahydropyranyl group or a 1-ethoxyethyl group.

In the photoresist composition, in one embodiment, the photosensitive polymer may have the weight-average molecular weight in a range of from about 5,000 up to about 50,000, and in another embodiment, the weight-average molecular weight in a range of from about 10,000 up to about 20,000. The photosensitive polymer is previously described so that a further description will be omitted.

When the photoresist composition includes less than about 1 part by weight of the photosensitive material based on about 100 parts by weight of the photosensitive polymer, an acid may not be sufficiently generated in a light-exposure process, and thus a developing rate of a light-exposed portion may be unacceptably deteriorated. In addition, when the content of the photosensitive material is greater than about 15 parts by weight, a light absorbance may excessively increase and a portion of a photoresist film may not be sufficiently exposed to light so that a clear pattern may not be obtained, which can also be unacceptable. Thus, the photoresist composition of the present invention may in one embodiment include from about 1 to about 15 parts by weight of the photosensitive material, based on about 100 parts by weight of the photosensitive polymer.

Examples of the photosensitive material may include a triarylsulfonium salt, a diaryliodonium salt, a sulfonate, an N-hydroxysuccinimide triflate, etc. These can be used alone or in a mixture thereof.

Particularly, examples of the photosensitive material may include triphenylsulfonium triflate, triphenylsulfonium antimony salt, diphenyliodonium triflate, diphenyliodonium antimony salt, methoxydiphenyliodonium triflate, di-tert-butyldiphenyliodonium triflate, 2,6-dinitrobenzyl sulfonate, pyrogallol tris (alkylsulfonate), norbornene-dicarboxylmide triflate, triphenylsulfonium nonaflate, diphenyliodonium nonaflate, methoxydiphenyliodonium nonaflate, di-tert-butyldiphenyliodonium nonaflate, N-hydroxysuccinimide nonaflate, norbornene dicarboxyimide nonaflate, triphenylsulfonium perfluorooctanesulfonate, diphenyliodonium perfluorooctanesulfonate, methoxyphenyliodonium perfluorooctanesulfonate, di-tert-butyldiphenyliodonium triflate, N-hydroxysuccinimide perfluorooctanesulfonate, norbornene dicarboxyimide perfluorooctanesulfonate, etc. These can be used alone or in a mixture thereof.

When the photoresist composition includes less than about 500 parts by weight of the organic solvent based on about 100 parts by weight of the photosensitive polymer, viscosity of the photoresist composition may excessively increase so that a photoresist film having a uniform thickness may not be formed, which can be unacceptable. In addition, when the content of the organic solvent is greater than about 20,000 parts by weight, a photoresist film having a sufficient thickness may not be formed, which is also unacceptable. Thus, the photoresist composition of the present invention may preferably include from about 500 up to about 20,000 parts by weight of the organic solvent based on about 100 parts by weight of the photosensitive polymer.

Examples of the organic solvent may include ethylene glycol monomethyl ether, ethylene glycol monoethyl ether, propylene glycol methyl ether, methylcellosolve acetate, ethylcellosolve acetate, diethylene glycol monomethyl ether, diethylene glycol monoethyl ether, propylene glycol methyl ether acetate, propylene glycol propyl ether acetate, diethylene glycol dimethyl ether, ethyl lactate, toluene, xylene, methyl ethyl ketone, cyclohexanone, 2-heptanone, 3-heptanone, 4-heptanone, etc. These can be used alone or in a combination thereof.

In an embodiment of the present invention, the photoresist composition may further include an organic base. The organic base may prevent a photoresist pattern from being affected by a basic compound (e.g., an amine) in the atmosphere, and may serve to control the shape of the photoresist pattern.

When the photoresist composition includes less than about 0.01 parts by weight of the organic base based on about 100 parts by weight of the photosensitive polymer, the photoresist pattern may not be formed in a sufficiently desirable shape, which can be unacceptable. In addition, the organic base of greater than about 20 parts by weight may not be economically desirable. Thus, the photoresist composition in one embodiment may include from about 0.01 up to about 20 parts by weight of the organic base, based on about 100 parts by weight of the photosensitive polymer.

Examples of the organic base may include triethylamine, triisobutylamine, triisooctylamine, triisodecylamine, diethanolamine, triethanolamine, etc. These can be used alone or in a mixture thereof.

The photoresist composition of the present invention may further include an additive such as a surfactant, a sensitizer, an adhesive, a preservation stabilizer, etc. Examples of the surfactant may include an ether compound such as polyoxyethylene lauryl ether, polyoxyethylene stearyl ether, polyoxyethylene oleyl ether, polyoxyethylene nonylphenyl ether, etc. The sensitizer, the adhesive and the preservation stabilizer may include an amine-based compound and the like. The photoresist composition may preferably include about 5 parts by weight of the additive, based on about 100 parts by weight of the photosensitive polymer.

Method of Forming a Photoresist Pattern

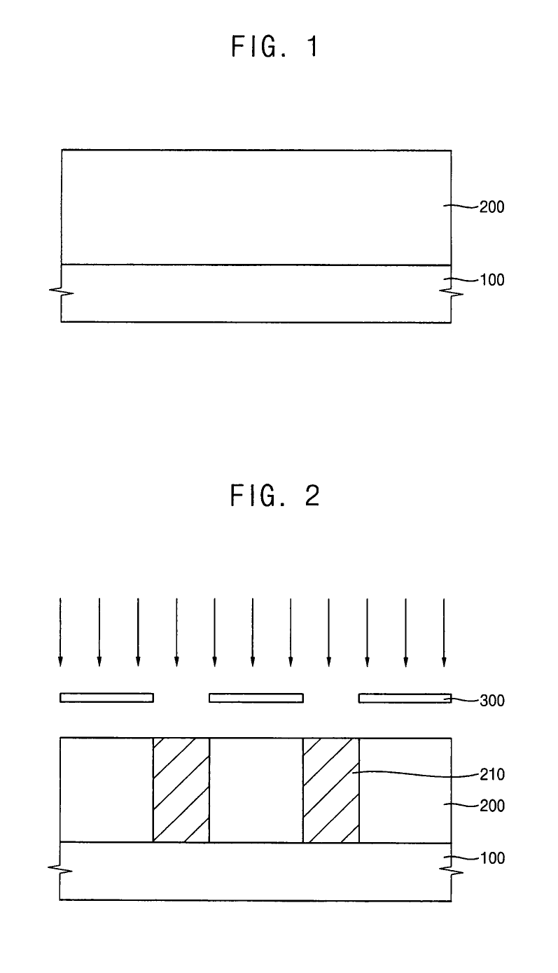

FIGS. 1 to 3 are cross-sectional views illustrating a method of forming a photoresist pattern in accordance with certain example embodiments. FIG. 1 is a cross-sectional view illustrating a photoresist film 200 formed on a substrate 100.

Referring to FIG. 1, an object is prepared. The substrate 100 such as a silicon wafer may be used as the object. The present embodiment will be described with respect to the substrate 100, hereinafter. Various structures (not illustrated) such as a gate, a capacitor, a wiring, a plug, an insulation layer or the like may be formed on the substrate 100. A surface treatment process may be selectively performed for the substrate 100 to remove moisture and/or a contaminant on the substrate 100. The moisture and/or the contaminant on the substrate 100 may deteriorate the adhesive characteristics of the photoresist film 200. In the surface treatment process, the substrate 100 may be fixed to a chuck, and then a fabric brush may make contact with the substrate 100 that rotates at a high speed and rapidly cleans the substrate 100. Thus, the moisture and/or the contaminant may be removed from the substrate 100 in the surface treatment process.

In one embodiment, the photoresist film 200 is formed on the substrate 100 by coating it with a photoresist composition including a photosensitive material, an organic solvent and a photosensitive polymer having a first repeating unit (a) represented by chemical formula (1) and a second repeating unit (b) represented by chemical formula (2), (a) and (b) being at a molar ratio of from about 40:60 to about 60:40,

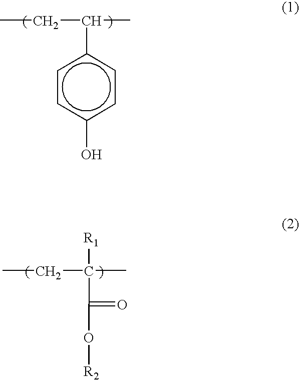

wherein R₁ represents hydrogen or an alkyl group having 1 to 10 carbon atoms and R₂ represents an acid-labile hydrocarbon group having 3 to 12 carbon atoms.

In the method of forming a photoresist pattern according to an embodiment of the present invention, R₁ in the chemical formula (2) may in one embodiment represent a methyl group, an ethyl group, a propyl group or a butyl group, and in another embodiment, a methyl group. R₂ in the chemical formula (2) may represent a tert-butyl group, a tetrahydropyranyl group or a 1-ethoxyethyl group.

The photoresist film 200 may be formed using a spin-coating process. Particularly, the chuck may be rotated at high speed. When the substrate 100 is rotated, the photoresist composition may be uniformly coated on the substrate 100 to form the photoresist film 200. Additionally, an anti-reflective layer (not shown) may be formed on the substrate 100.

In the method of forming a photoresist pattern, the photosensitive polymer may in one embodiment have the weight-average molecular weight in a range of from about 5,000 to about 50,000, and in another embodiment, the weight-average molecular weight can be in a range of about 10,000 to about 20,000. The photosensitive material and the organic solvent are previously described so that this description will be omitted.

A first baking process may be performed for the substrate 100 including the photoresist film 200 thereon. The first baking process may be performed at a temperature of from about 90° C. up to about 120° C. The first baking process may enhance adhesive characteristics between the photoresist film 200 and the substrate 100.

Referring to FIG. 2, the substrate 100 can be exposed to light. Particularly, a mask 300 on which a predetermined pattern is formed is positioned on a mask stage of an exposure apparatus. The mask 300 is arranged over the substrate 100 having the photoresist film 200 thereon in an alignment process. An illumination light is irradiated onto the mask 300 for a desirable time so that a portion of the photoresist film 200 may be selectively reacted with light through the mask 300. Examples of the light may include a G-line ray, an I-line ray, a krypton fluoride laser, an argon fluoride laser, an electron beam, an X-ray, etc. The illumination light may in one embodiment include an ArF laser used for a high resolution imaging. An exposed portion 210 of the photoresist film 200 may have solubility different from that of an unexposed portion of the photoresist film 200.

After the exposing process, a second baking process may be additionally performed for the substrate 100. The second baking process may be performed at a temperature of from about 90° C. up to about 150° C. In the second baking process, solubility of the exposed portion 210 may be further changed so that the exposed portion 210 may be easily dissolved in a particular solvent.

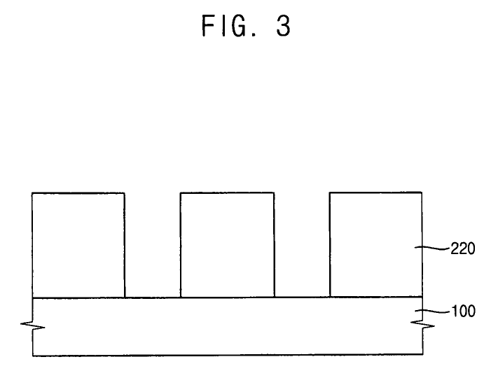

Referring to FIG. 3, the exposed portion 210 can be removed using a developing solution to form the photoresist pattern 220 on the substrate 100. For example, the exposed portion 210 can be removed using an aqueous solution of tetramethylammonium hydroxide (TMAH), etc.

The substrate 100 including the photoresist pattern 220 thereon may be cleaned, and then other ordinary processes may be performed. Various structures of a semiconductor device may be formed using the photoresist pattern 220 as a mask.

The photoresist composition of the present invention will be further described in the Example and Comparative Examples below.

Preparation of the Photoresist Composition

### EXAMPLE 1

A photoresist composition was prepared by mixing about 4 percent by weight of a photosensitive polymer of the present invention, about 0.3 percent by weight of triphenylsulfonium perfluorooctanesulfonate as a photosensitive material, about 0.15 percent by weight of trimethylamine as an organic base, about 0.55 percent by weight of ethylene glycol as an additive, and about 95 percent by weight of an organic solvent including propylene glycol methyl ether and ethyl lactate in a weight ratio of about 8:2. The photosensitive polymer was a random copolymer of p-hydroxystyrene and t-butyl methacrylate, which had a molar ratio of about 50:50 (i.e., about 1:1). The weight-average molecular weight of the photosensitive polymer was about 15,890.

### EXAMPLE 2

A photoresist composition was prepared by performing processes substantially the same as those of Example 1 except that the molar ratio of p-hydroxystyrene and t-butyl methacrylate in the photosensitive polymer was about 40:60.

### COMPARATIVE EXAMPLE 1

A conventional photoresist composition was prepared by mixing about 4 percent by weight of SEPR-146 (trade name manufactured by Shin-Etsu Chemical Co., Japan), about 0.3 percent by weight of triphenylsulfonium perfluorooctanesulfonate as a photosensitive material, about 0.15 percent by weight of trimethylamine as an organic base, about 0.55 percent by weight of ethylene glycol as an additive, and about 95 percent by weight of an organic solvent including propylene glycol methyl ether and ethyl lactate in a weight ratio of about 8:2.

### COMPARATIVE EXAMPLE 2

A photoresist composition was prepared by mixing about 4 percent by weight of a photosensitive polymer, about 0.3 percent by weight of triphenylsulfonium perfluorooctanesulfonate as a photosensitive material, about 0.15 percent by weight of trimethylamine as an organic base, about 0.55 percent by weight of ethylene glycol as an additive, and about 95 percent by weight of an organic solvent including propylene glycol methyl ether and ethyl lactate in a weight ratio of about 8:2. The photosensitive polymer was a random copolymer of p-hydroxystyrene and t-butyl methacrylate, which had a molar ratio of about 65:35. The weight-average molecular weight of the photosensitive polymer was about 15,850.

### COMPARATIVE EXAMPLES 3 AND 4

Photoresist compositions were prepared by performing processes substantially the same as those of Example 1 except for the molar ratio of p-hydroxystyrene and t-butyl methacrylate in the photosensitive polymer. The molar ratio between p-hydroxystyrene and t-butyl methacrylate was about 35:65 (Comparative Example 3), and about 20:80 (Comparative Example 4).

Evaluation of a Thickness Distribution of a Photoresist Film

Photoresist films were respectively formed on a substrate using the photoresist compositions prepared in Example 1 and Comparative Example 1. The photoresist films having a thickness of about 3,500 Å were formed on the substrate.

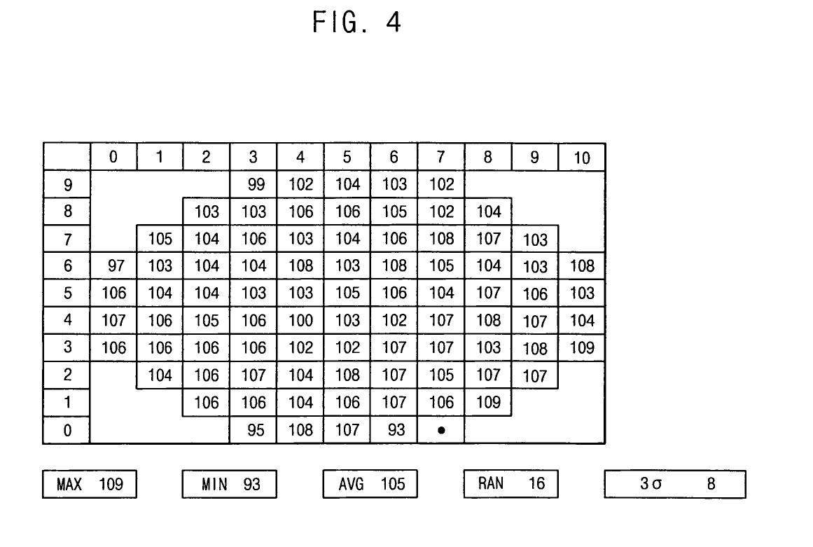

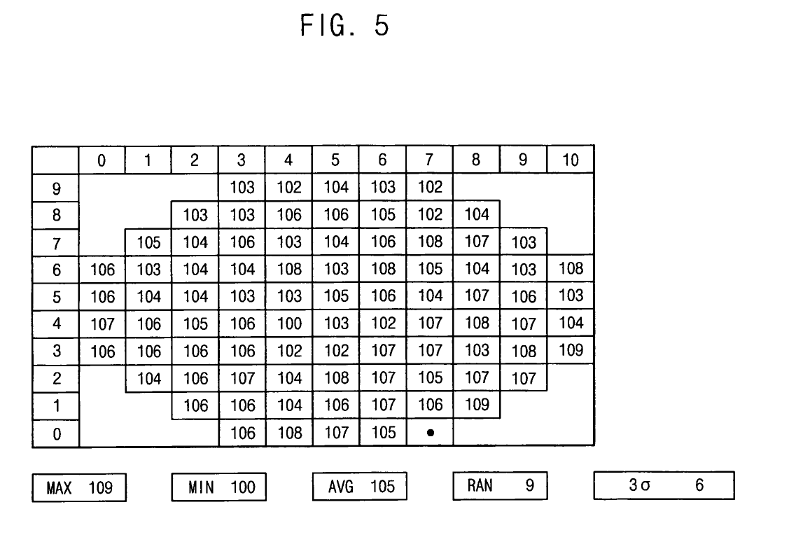

FIGS. 4 and 5 are plan views illustrating thickness distributions of photoresist films after forming the photoresist films using photoresist compositions prepared in Example 1 and Comparative Example 1. Particularly, FIG. 4 is a view illustrating the thickness distribution of the photoresist film formed using the photoresist composition prepared in Comparative Example 1. FIG. 5 is a view illustrating the thickness distribution of the photoresist film formed using the photoresist composition prepared in Example 1.

Referring to FIGS. 4 and 5, when the photoresist film was formed using the photoresist composition prepared in Comparative Example 1, a maximum thickness of the photoresist film was about 109 nm and the minimum thickness was about 93 nm. The maximum thickness difference of the photoresist film was about 16 nm, and the 3σ value was about 8. However, when the photoresist film was formed using the photoresist composition prepared in Example 1, the maximum thickness of the photoresist film was about 109 nm and a minimum thickness was about 100 nm. The maximum thickness difference of the photoresist film was about 9 nm, and the 3σ value was about 6. The photoresist film formed using the photoresist composition of the subject photoresist composition has a thickness dispersion substantially narrower than that of the conventional photoresist composition. Therefore, the subject photoresist composition can form a photoresist film having a uniform thickness.

Evaluation of Line Edge Roughness of a Structure Pattern

Photoresist films were respectively formed on a substrate using the photoresist compositions prepared in Example 1 and Comparative Example 1. The photoresist films having a thickness of about 3,500Å were formed on the substrate including a structure thereon. Particularly, an oxide layer having a thickness of about 150 Å was formed on the substrate, and then a silicon nitride layer having a thickness of about 980 Å was formed on the oxide layer to thereby form the structure on the substrate. The photoresist film was exposed using a krypton fluoride laser through a mask having a predetermined pattern. An exposure doze was about 57 mJ, and ASML850 (trade name manufactured by ASML, Netherlands) was used as the exposure apparatus. A portion of the photoresist film was removed using tetramethylammonium hydroxide solution as a developing solution to form a photoresist pattern on the structure. The silicon nitride layer was dry etched using the photoresist pattern as an etching mask to thereby form a silicon nitride layer pattern on the oxide layer.

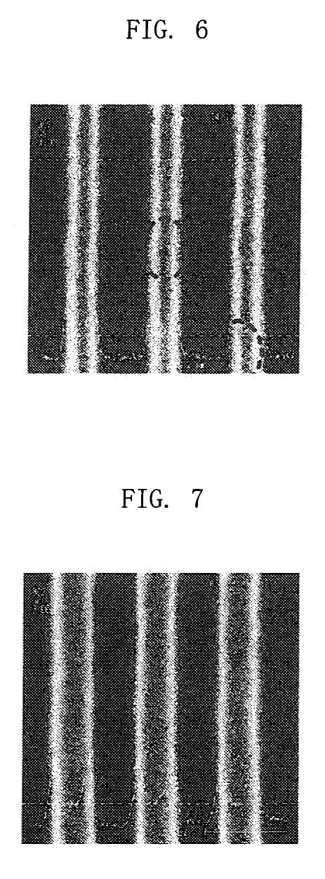

FIGS. 6 and 7 are scanning electron microscopic (SEM) pictures illustrating the silicon nitride layer patterns etched using the photoresist patterns as etching masks, the photoresist patterns being formed using photoresist compositions prepared in Example 1 and Comparative Example 1. Particularly, FIG. 6 is a SEM picture illustrating the silicon nitride layer pattern etched using the photoresist pattern as an etching mask, the photoresist pattern being formed using the photoresist composition prepared in Comparative Example 1. FIG. 7 is a SEM picture illustrating the silicon nitride layer pattern etched using the photoresist pattern as an etching mask, the photoresist pattern being formed using the photoresist composition prepared in Example 1.

Referring to FIGS. 6 and 7, when the silicon nitride layer pattern was etched using the photoresist pattern that was formed by the photoresist composition prepared in Comparative Example 1, line edge roughness of the silicon nitride layer pattern was deteriorated. In other words, edge portions of the silicon nitride layer pattern had a relatively severe roughness, and the silicon nitride layer pattern had poor profiles. However, when the silicon nitride layer pattern was etched using the photoresist pattern that was formed by the photoresist composition prepared in Example 1, the silicon nitride layer pattern had a good profile compared with that of Comparative Example 1. Therefore, when the structure pattern is formed using the photoresist pattern formed by the photoresist composition of the present invention, a fine pattern may be formed with accuracy.

Additionally, photoresist patterns were respectively formed on silicon wafers using the photoresist compositions prepared in Examples 1, 2, and Comparative Example 2 to 4. After each photoresist film was formed on the silicon wafer, the photoresist film was baked at a temperature of about 105° C. for about 50 seconds. The thickness of the photoresist film was about 1,500A. An exposure process was carried out using an ArF laser having a wavelength of about 193 nm. After performing the exposure process, the photoresist film was baked at a temperature of about 110° C. for about 50 seconds. The photoresist film was developed using a developing solution including about 2.38% by weight of tetramethylammonium hydroxide and water.

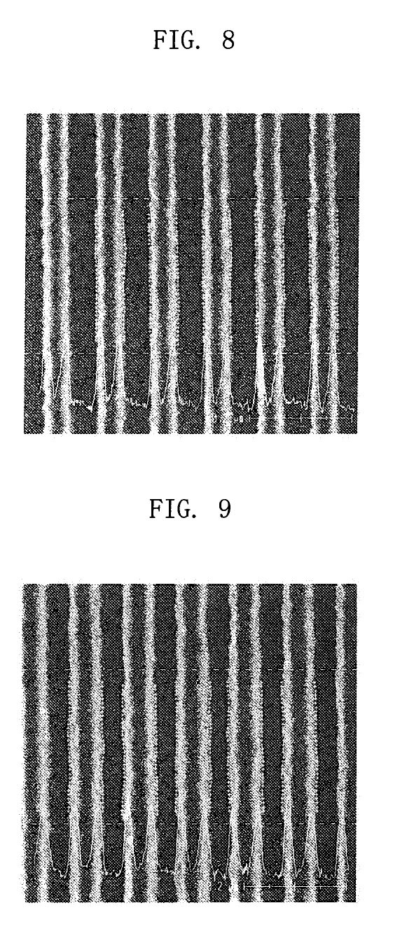

FIGS. 8 and 9 are SEM pictures showing the photoresist patterns formed using the photoresist compositions of Example 1 and Comparative Example 2.

As shown in FIG. 8, the photosensitive polymer of which had a molar ratio of about 1:1 produced the photoresist pattern having an enhanced profile formed in a fine pattern formed in a more exact manner and having a substantially reduced line edge roughness. However, as shown in FIG. 9, the photoresist pattern formed using the polymer having a molar ratio of about 65:35 had a profile formed in a much lesser quality pattern in a lesser exact manner and having a substantially higher line edge roughness than the photoresist pattern of FIG. 8.

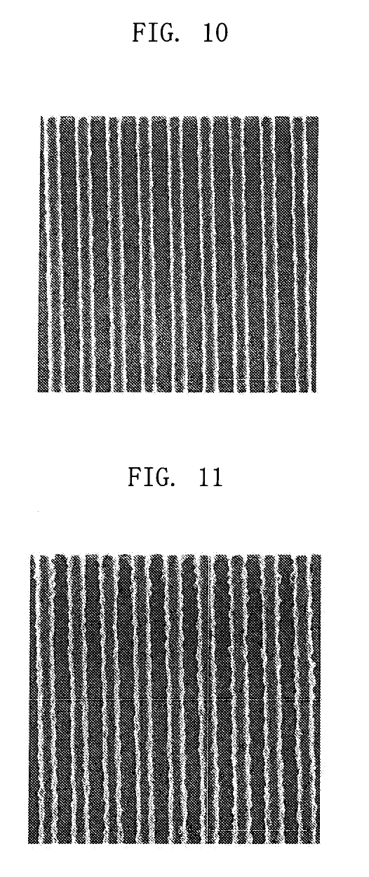

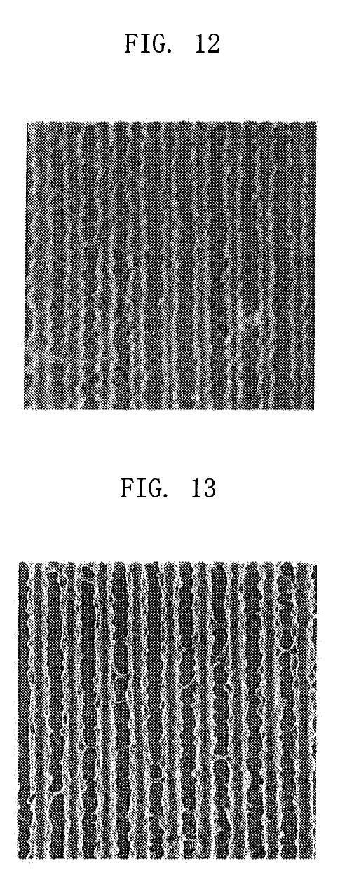

FIGS. 10 to 13 are SEM pictures showing the photoresist patterns formed using the photoresist compositions of Examples 1 and 2 and Comparative Examples 3 and 4. FIG. 10 is an SEM picture showing the photoresist pattern formed using the photoresist composition of Example 1; FIG. 11 is an SEM picture obtained using the photoresist composition of the Example 2; FIG. 12 is an SEM picture obtained using the photoresist composition of Comparative Example 3; and FIG. 13 is an SEM picture obtained using the photoresist composition of Comparative Example 4.

As shown in FIGS. 12 and 13, the photosensitive polymer of which had a molar ratio of about 35:65 or about 20:80 generated a bridge between photoresist patterns and produced a photoresist pattern having a poor profile. However, as shown in FIG. 11, the photoresist pattern obtained using the photosensitive polymer at a molar ratio of about 40:60 had a good profile and a reduced line edge roughness. Furthermore, as shown in FIG. 10, the photoresist pattern formed using the photosensitive polymer at a molar ratio of about 50:50 exhibited an excellent profile formed in a more exact manner and a greatly reduced line edge roughness. A measured line edge roughness of the photoresist pattern obtained using the photosensitive polymer at a molar ratio of about 40:60 was less than about 9.3 nm, and the line edge roughness of the photoresist pattern obtained using the photosensitive polymer at a molar ratio of about 50:50 was less than about 5.2 nm.

According to the present invention, a photoresist composition may prevent a development difference of a photoresist film due to a different wetting time of each portion of the photoresist film with a developing solution. Thus, a photoresist pattern having a uniform thickness may be obtained. Furthermore, when a photoresist pattern is formed using the photoresist composition of the present invention, the photoresist pattern may reduce line edge roughness and an extremely fine pattern may be formed in a more exact manner. Therefore, the aforementioned defects of a semiconductor device may be prevented and the productivity of a semiconductor manufacturing process may be enhanced.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A photoresist composition comprising:
a photosensitive polymer consisting essentially of a first repeating unit (a) represented by chemical formula (1) and a second repeating unit (b) represented by chemical formula (2), (a) and (b) being at a molar ratio of from about 40:60 to about 60:40, 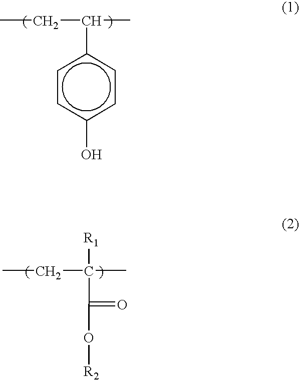
wherein R₁ represents hydrogen or an alkyl group having 1 to 10 carbon atoms and R₂ represents an acid-labile hydrocarbon group having 3 to 12 carbon atoms;
a photosensitive material; and
an organic solvent.

2. The photoresist composition of claim 1, wherein the first repeating unit (a) and the second repeating unit (b) are at a molar ratio of from about 45:55 to about 55:45.

3. The photoresist composition of claim 1, wherein the first repeating unit (a) and the second repeating unit (b) are at a molar ratio of about 1:1.

4. The photoresist composition of claim 1, wherein R₁ represents a methyl group, an ethyl group, a propyl group or a butyl group.

5. The photoresist composition of claim 1, wherein R₂ represents a tert-butyl group, a tetrahydropyranyl group or a 1-ethoxyethyl group.

6. The photoresist composition of claim 1, wherein the photosensitive polymer has a weight-average molecular weight in a range of from about 5,000 up to about 50,000.

7. The photosensitive composition of claim 1, wherein the photosensitive polymer has a weight-average molecular weight in a range of from about 10,000 up to about 20,000.

8. The photoresist composition of claim 1, wherein the photoresist composition comprises from about 1 up to about 15 parts by weight of the photosensitive material, based on about 100 parts by weight of the photosensitive polymer.

9. The photoresist composition of claim 1, wherein the photosensitive material comprises at least one of a triarylsulfonium salt, a diaryliodonium salt, a sulfonate and an N-hydroxysuccinimide triflate.

10. The photoresist composition of claim 1, wherein the organic solvent comprises at least one of ethylene glycol monomethyl ether, ethylene glycol monoethyl ether, propylene glycol methyl ether, methylcellosolve acetate, ethylcellosolve acetate, diethylene glycol monomethyl ether, diethylene glycol monoethyl ether, propylene glycol methyl ether acetate, propylene glycol propyl ether acetate, diethylene glycol dimethyl ether, ethyl lactate, toluene, xylene, methyl ethyl ketone, cyclohexanone, 2-heptanone, 3-heptanone and 4-heptanone.

11. The photoresist composition of claim 1, further comprising an organic base.

12. The photoresist composition of claim 11, wherein the photoresist composition comprises from about 0.01 up to about 20 parts by weight of the organic base, based on about 100 parts by weight of the photosensitive polymer.

13. The photoresist composition of claim 11, wherein the organic base comprises at least one of triethylamine, triisobutylamine, triisooctylamine, triisodecylamine, diethanolamine and triethanolamine.

14. A method of forming a photoresist pattern comprising:
forming a photoresist film on an object by coating the object with a photoresist composition including a photosensitive material, an organic solvent and a photosensitive polymer consisting essentially of a first repeating unit (a) represented by chemical formula (1) and a second repeating unit (b) represented by chemical formula (2), (a) and (b) being at a molar ratio of about from about 40:60 to about 60:40, 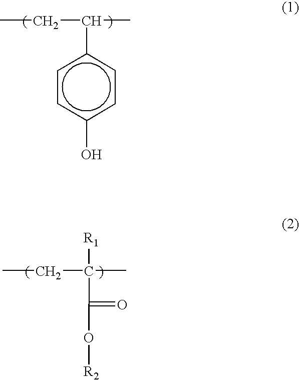
wherein R₁ represents hydrogen or an alkyl group having 1 to 10 carbon atoms and R₂ represents an acid-labile hydrocarbon group having 3 to 12 carbon atoms;
exposing the photoresist film to a light through a mask; and
removing a portion of the photoresist film to form a photoresist pattern.

15. The method of claim 14, wherein the first repeating unit (a) and the second repeating unit (b) are at a molar ratio of from about 45:55 to about 55:45.

16. The method of claim 14, wherein the first repeating unit (a) and the second repeating unit (b) are at a molar ratio of about 1:1.

17. The method of claim 14, wherein the photoresist film is exposed to the light comprising an argon fluoride (ArF) laser.

18. The method of claim 14, prior to exposing the photoresist film to the light, further comprising baking of the photoresist film at a temperature of from about 90° C. up to about 120° C.

19. The method of claim 14, further comprising baking of the photoresist film at a temperature of about 90° C. to about 150° C. after exposing the photoresist film to the light.

20. The method of claim 14, wherein the photoresist composition comprises from about 1 up to about 15 parts by weight of the photosensitive material, based on about 100 parts by weight of the photosensitive polymer.
